(19) United States
(12) Patent Application Publication
(10) Pub. No.: US 2025/0133773 A1
(43) Pub. Date: Apr. 24, 2025

(54) STACKED NANOSHEET GATE-ALL-AROUND DEVICE WITH AIR SPACER AND METHOD OF MANUFACTURING STACKED NANOSHEET GATE-ALL-AROUND DEVICE WITH AIR SPACER

(71) Applicant: INSTITUTE OF MICROELECTRONICS, CHINESE ACADEMY OF SCIENCES, Beijing (CN)

(72) Inventors: Qingzhu ZHANG, Beijing (CN); Lianlian LI, Beijing (CN); Anyan DU, Beijing (CN); Huaxiang YIN, Beijing (CN); Lei CAO, Beijing (CN); Jiaxin YAO, Beijing (CN); Zhaohao ZHANG, Beijing (CN); Qingkun LI, Beijing (CN); Guanqiao SANG, Beijing (CN)

(21) Appl. No.: 18/915,723

(22) Filed: Oct. 15, 2024

(30) Foreign Application Priority Data
Oct. 20, 2023 (CN) 202311367875.0

(51) Int. Cl. H01L 29/423; H01L 21/822; H01L 27/06; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 84/038; H10D 84/856; H10D 88/00; H10D 88/01

(57) ABSTRACT

The present disclosure relates to a stacked nanosheet gate-all-around device with an air spacer and a method of manufacturing a stacked nanosheet gate-all-around device with an air spacer. The stacked nanosheet gate-all-around device with the air spacer includes: a substrate with a shallow trench isolation structure on a surface of the substrate; a nanosheet stacking portion provided above the substrate, where the nanosheet stacking portion includes a stack formed by a plurality of nanosheets, and the stack formed by the nanosheets constitutes a plurality of conductive channels; a gate-all-around surrounding the nanosheet stacking portion; and a source/drain region located on two opposite sides of the nanosheet stacking portion, where an empty spacer is provided between the source/drain region and the gate-all-around, where an interior of the empty spacer is filled with at least one of air, a reducing gas, or an inert gas.

### CROSS REFERENCE TO RELATED APPLICATION

This application claims priority to Chinese Patent Application No. 202311367875.0, filed on Oct. 20, 2023, the entire content of which is incorporated herein in its entirety by reference.

### TECHNICAL FIELD

The present disclosure relates to a field of transistors, and in particular to a stacked nanosheet gate-all-around device with an air spacer and a method of manufacturing a stacked nanosheet gate-all-around device with an air spacer.

### BACKGROUND

With the continuous miniaturization of feature sizes of transistors, the conventional CMOS device undergoes a transition from a planar structure to a three-dimensional structure, which improves the device performance while reducing the impact of the short channel effect. At present, the mainstream three-dimensional structure transistor is FinFET. In the latest International Roadmap for Devices and Systems (IRDS), Nanosheet Gate-all-around Transistor (Nanosheet-GAAFET) is a key device that may effectively replace FinFET after a 3 nm node, which may significantly suppress the short channel effect and improve the current driving performance of the device. At present, the research progress of Nanosheet-GAAFET has received widespread attention from both academia and industry.

The preparation process of the stacked Nanosheet-GAAFET is compatible with the preparation process of the mainstream FinFET. Compared with the traditional FinFET device, a parasitic capacitance of the stacked Nanosheet-GAAFET device increases sharply due to the greatly increased area from the gate to the source/drain and from the gate to the sub-fin, which will significantly reduce an operating speed of a circuit. Therefore, it is desired to use a material with a low dielectric constant as a spacer to reduce the parasitic capacitance, and air is considered the most ideal low-k material. In the FinFET device, the air gap is proved to be capable of effectively reducing the impact of parasitic capacitance, but a series of problems such as the process is unstable, the structure is difficult to control accurately and the like exist.

### SUMMARY

A first aspect of the present disclosure provides a stacked nanosheet gate-all-around device with an air spacer, including:
a substrate with a shallow trench isolation structure on a surface of the substrate;
a nanosheet stacking portion provided above the substrate, where the nanosheet stacking portion includes a stack formed by a plurality of nanosheets, and the stack formed by the nanosheets constitutes a plurality of conductive channels;
a gate-all-around surrounding the nanosheet stacking portion; and
a source/drain region located on two opposite sides of the nanosheet stacking portion, where an empty spacer is provided between the source/drain region and the gate-all-around,
where an interior of the empty spacer is filled with at least one of air, a reducing gas, or an inert gas.

Furthermore, the stacked nanosheet gate-all-around device with the air spacer further includes a second dielectric layer surrounding and covering the gate-all-around,
where the gate-all-around includes an interlayer gate filled among the plurality of nanosheets and a peripheral gate surrounding the nanosheet stacking portion, and
where the empty spacer includes a first empty spacer located between the second dielectric layer and the peripheral gate, and a second empty spacer located between the interlayer gate and the source/drain region.

Furthermore, the nanosheet is made of a silicon germanium material.

Furthermore, a width of the nanosheet is in a range of 5 nm to 50 nm, and a thickness of the nanosheet is in a range of 3 nm to 20 nm.

Furthermore, the shallow trench isolation structure is made of silicon oxide.

Furthermore, the gate-all-around includes a gate dielectric layer and a metal gate layer.

A second aspect of the present disclosure provides a method of manufacturing a stacked nanosheet gate-all-around device with an air spacer, which may be used to manufacture the device in the first aspect. The method includes:
providing a substrate;
forming a sacrificial layer on the substrate;
forming a first semiconductor layer on an upper surface of the sacrificial layer;
epitaxially growing a superlattice stack on a surface of the first semiconductor layer, wherein the superlattice stack is composed of different semiconductor materials alternatively stacked;
etching the superlattice stack and a partial thickness of the first semiconductor layer to form a fin;
forming a first dielectric layer on the first semiconductor layer as a shallow trench isolation, wherein an upper surface of the first dielectric layer is not higher than a bottom of the superlattice stack;
depositing a dummy gate on the fin and forming a first spacer on a sidewall of the dummy gate;
etching the superlattice stack in the fin to release a source/drain area;
forming a second spacer on a sidewall of the superlattice stack in the fin;
depositing a doped semiconductor material in the source/drain area to form a source/drain region;
forming a second dielectric layer on the source/drain region, wherein the second dielectric layer is flush with the dummy gate;
removing the dummy gate;
etching off a part of the semiconductor materials in the superlattice stack to release a nanosheet channel, wherein a stack formed by the nanosheets constitutes a plurality of conductive channels;
forming a gate-all-around to surround the stack formed by the nanosheets;
etching and removing the first spacer and the second spacer to form a first empty spacer and a second empty spacer, respectively, and filling a third dielectric layer.

Furthermore, the method further includes: replacing a gas in the first empty spacer and the second empty spacer with at least one of air, a reducing gas, or an inert gas.

Furthermore, the filling a third dielectric layer includes: filling silicon oxide by using a PECVD method.

Furthermore, the first spacer and the second spacer are made of silicon nitride, and the first spacer and the second spacer are etched by using a phosphoric acid solution.

### BRIEF DESCRIPTION OF THE DRAWINGS

Various other advantages and benefits will become clear to those ordinary skilled in the art by reading the detailed description of the preferred embodiments below. The drawings are only for the purpose of illustrating the preferred embodiments, and are not considered as limitation of the present disclosure.

FIG. 1 to FIG. 14 show schematic diagrams of structures obtained at various steps in a method of manufacturing a stacked nanosheet gate-all-around device provided by the present disclosure.

FIG. 15 shows a cross-sectional view of a stacked nanosheet gate-all-around device provided by the present disclosure in Y-Y′ direction.

FIG. 16 shows a cross-sectional view of a stacked nanosheet gate-all-around device provided by the present disclosure in X-X′ direction.

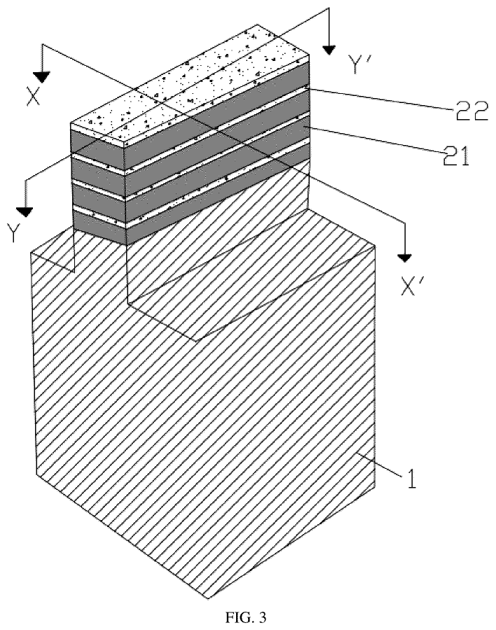

The X-X′ and Y-Y′ directions in the above figures are referenced to the directions indicated in FIG. 3.

### DETAILED DESCRIPTION OF EMBODIMENTS

Hereinafter, embodiments of the present disclosure will be described with reference to the drawings. However, it should be understood that these descriptions are only exemplary and are not intended to limit the scope of the present disclosure. In addition, in the following illustration, descriptions of well-known structures and technologies are omitted to avoid unnecessarily confusing the concepts of the present disclosure.

Various structural schematic diagrams according to the embodiments of the present disclosure are shown in the drawings. These drawings are not drawn to scale, in which some details are enlarged and some details may be omitted for the purpose of clear expression. The shapes, the relative sizes and the positional relationships of various regions and layers shown in the drawings are only exemplary, and may actually be deviated due to manufacturing tolerances or technical limitations. Moreover, those skilled in the art may additionally design regions/layers with different shapes, sizes and relative positions according to actual needs.

In the context of the present disclosure, when a layer/element is described to be “on” a further layer/element, the layer/element may be directly on the further layer/element, or there may be an intermediate layer/element therebetween. In addition, if a layer/element is “on” a further layer/element in one orientation, the layer/element may be “below” the further layer/element when the orientation is reversed.

The main objective of the present disclosure is to provide a stacked nanosheet gate-all-around device with an air spacer and a method of manufacturing a stacked nanosheet gate-all-around device with an air spacer. In the present disclosure, an air spacer is introduced in the Nanosheet-GAAFET as a spacer between a source/drain region and a gate, so that the parasitic capacitance of the device is greatly reduced, the process is stable, and the structure may be accurately controlled.

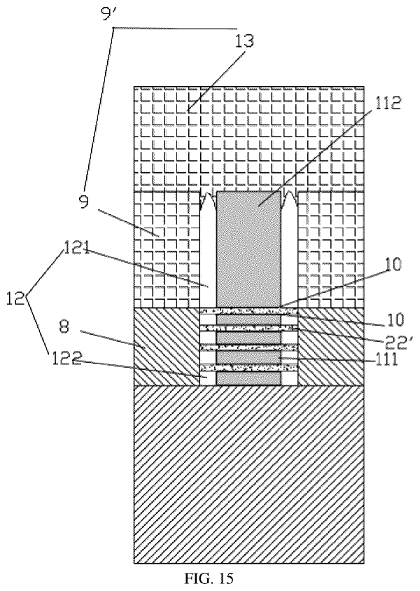

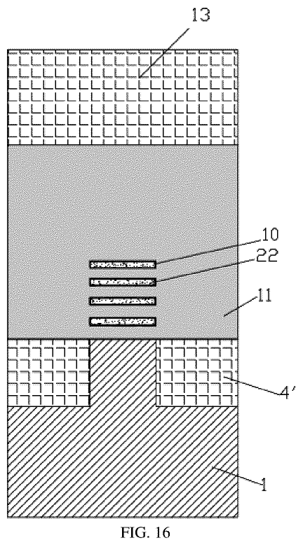

The present disclosure provides a Nanosheet-GAAFET with an all-air spacer structure as shown in FIG. 15 and FIG. 16.

The Nanosheet-GAAFET with the all-air spacer structure provided in the present disclosure includes:
a substrate 1 with a shallow trench isolation structure 4′ on a surface of the substrate 1;
a nanosheet stacking portion provided above the substrate, where the nanosheet stacking portion includes a stack formed by a plurality of nanosheets 22′, and the stack formed by the nanosheets 22′ constitutes a plurality of conductive channels;
a gate-all-around surrounding the nanosheet stacking portion; and
a source/drain region 8 located on two opposite sides of the nanosheet stacking portion, where an empty spacer 12 is provided between the source/drain region 8 and the gate-all-around,
where an interior of the empty spacer 12 is filled with at least one of air, a reducing gas, or an inert gas.

Therefore, in the present disclosure, a gas medium such as air is used as the isolation material (the gap unit and the empty spacer are filled with the gas) at a plurality of positions, including providing an empty spacer 12 between the source/drain region 8 and the gate-all-around, thereby significantly reducing the parasitic capacitance of the device and effectively improving the operating speed of the device and the circuit.

The semiconductor material spaced between the shallow trench isolation structures 4′ is in one-to-one correspondence with the nanosheet stacking portion. Here, “one set of nanosheet stacking portions” refers to one fin, i.e., one vertically stacked unit. The empty spacer 12 is a cavity structure, and the gas filled inside may be naturally circulating air during the preparation process, or a reducing gas or an inert gas after replacing the air, including but not limited to hydrogen, nitrogen, argon, and the like.

The Nanosheet-GAAFET of the present disclosure may be an NMOS, a PMOS, or a mixed arrangement of NMOS and PMOS. The doping type of the source/drain region of the transistor is matched with the type of the transistor. Meanwhile, the doping type of the substrate is determined according to the transistor type.

The substrate 1 may be any substrate known to those skilled in the art for carrying elements of a semiconductor integrated circuit, such as silicon-on-insulator (SOI), bulk silicon, silicon carbide, germanium, silicon germanium, gallium arsenide or germanium-on-insulator. A corresponding top layer semiconductor material is silicon, germanium, silicon germanium, or gallium arsenide. The substrate may also be a stacked structure composed of a plurality of layers of semiconductor materials.

The material used for the shallow trench isolation may be selected from high-k dielectric materials such as oxide and oxynitride, e.g., typical silicon oxide (SiO₂), silicon oxynitride, silicon nitride (SiNₓ), and the like.

The nanosheet 22′ may be made of a semiconductor material such as silicon, silicon germanium, and the like. The source/drain region 8 may be made of a P-type or N-type doped semiconductor material, and the semiconductor materials used for the two may be the same or different.

For the convenience of encapsulating and protecting the circuit structure, a second dielectric layer 9′ may be further provided to surround and cover the gate-all-around. The second dielectric layer 9′ may be made of a high-k dielectric material such as oxide and oxynitride, e.g., typical silicon oxide (SiO₂), silicon oxynitride, silicon nitride (SiNₓ), and the like.

Meanwhile, the gate-all-around may include an interlayer gate 111 filled among the plurality of nanosheets and a peripheral gate 112 surrounding the nanosheet stacking portion.

According to different gate distribution positions and structures, the empty spacer 12 includes a first empty spacer 121 located between the second dielectric layer and the peripheral gate, and a second empty spacer 122 located between the interlayer gate and the source/drain region.

The first empty spacer 121 and the second empty spacer 122 are both filled with air or other gases as an isolation material.

The nanosheet in the above-mentioned stacked nanosheet gate-all-around device may have a width in a range of 5 nm to 50 nm and a thickness in a range of 3 nm to 20 nm, which has a high integration.

In some embodiments, the gate-all-around includes a gate dielectric layer 12 and a metal gate layer 11.

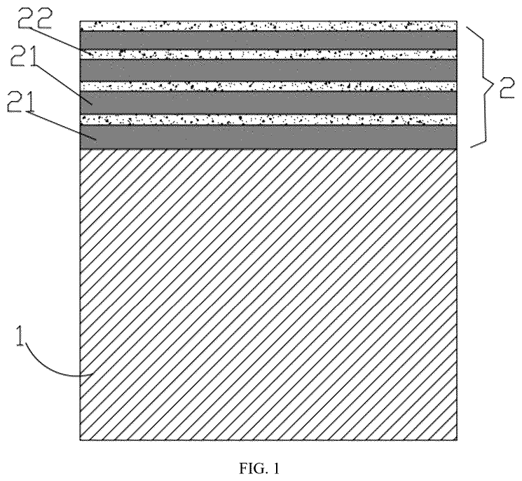

There are many methods of manufacturing the stacked nanosheet gate-all-around device described above. The present disclosure provides a manufacturing method in which the process is stable and the air spacer has excellent shape retention. The specific process is described below in conjunction with FIG. 1 to FIG. 16.

In Step S1, a substrate 1 is provided. The substrate 1 may be any substrate known to those skilled in the art for carrying elements of a semiconductor integrated circuit, such as silicon-on-insulator (SOI), bulk silicon, silicon carbide, germanium, silicon germanium, gallium arsenide or germanium-on-insulator. A corresponding top layer semiconductor material is silicon, germanium, silicon germanium, or gallium arsenide. Before proceeding to the next step, the substrate is cleaned, e.g., to remove an oxide layer from the surface of the substrate.

In Step S2, a superlattice stack 2, in which different semiconductor materials are alternately stacked, is epitaxially grown on a surface of the substrate 1, so as to obtain the structure shown in FIG. 1. The superlattice stack 2 may be an alternating stack of a silicon layer 21 and a silicon germanium layer 22, or other combinations.

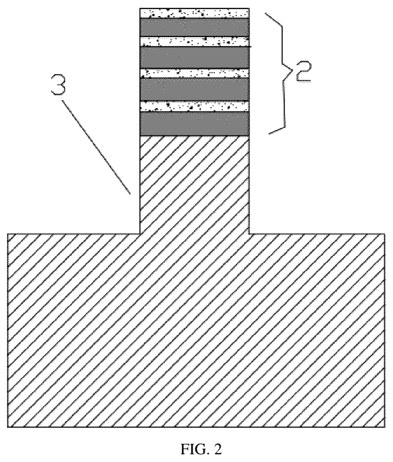

In Step S3, the superlattice stack 2 and a partial thickness of the substrate 1 are etched to form a fin 3, so as to obtain the structure shown in FIG. 2. FIG. 3 shows a three-dimensional view of the structure, and FIG. 2 shows a sectional view of FIG. 3 in the X-X′ direction. During etching, a functional layer such as a hard mask, a barrier layer and the like may be used to obtain a predetermined pattern. The partial thickness refers to that the etching is performed into the substrate 1 but does not penetrate the substrate 1. In this way, the substrate will also form a convex structure that is conformal with the nanosheet. Etching may be dry etching or wet etching, or combined with CMP or the like.

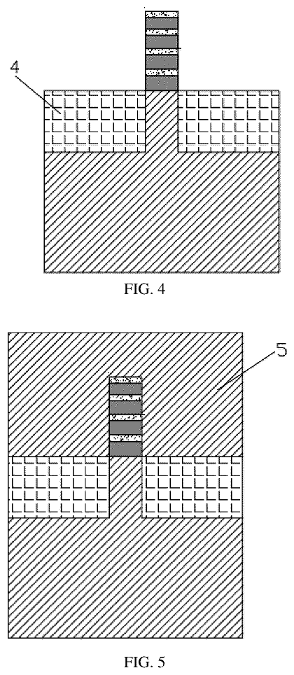

In Step S4, a first dielectric layer 4 is formed on the substrate 1 as a shallow trench isolation, and an upper surface of the first dielectric layer 4 is not higher than the bottom of the superlattice stack 2, as shown in FIG. 4. The shallow trench isolation is not higher than the bottom of the superlattice stack 2, so that the subsequently deposited gate may completely surround the nanosheet.

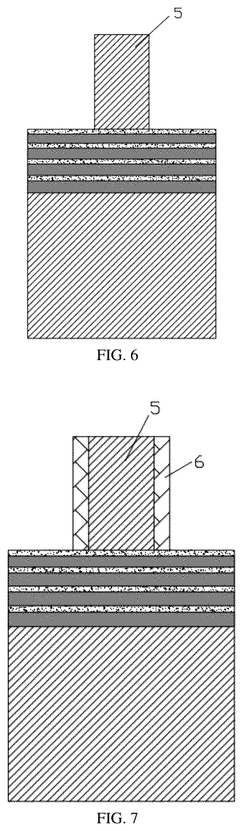

In Step S5, a dummy gate 5 is deposited on the fin 3, as shown in FIG. 5 and FIG. 6 (FIG. 5 shows a cross-sectional view in the X-X′ direction, and FIG. 6 shows a cross-sectional view in the Y-Y′ direction); and a first spacer 6 is deposited on a sidewall of the dummy gate 5, as shown in FIG. 7 (a cross-sectional view in the Y-Y′ direction). The dummy gate 5 may be made of polycrystalline silicon or amorphous silicon. The first spacer 6 may be made of a material having a high etching selectivity relative to the superlattice stack, such as silicon nitride. The deposition method includes but is not limited to PECVD, ALCVD, and the like.

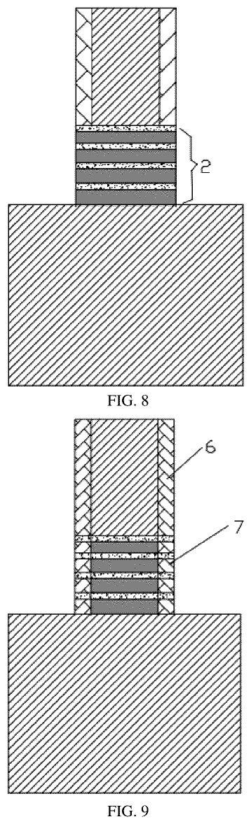

In Step S6, the superlattice stack 2 in the fin 3 is etched to release a source/drain area, as shown in FIG. 8 (a cross-sectional view in the Y-Y′ direction).

In Step S7, a second spacer 7 is formed on a sidewall of the superlattice stack 2 in the fin, as shown in FIG. 9 (a cross-sectional view in the Y-Y′ direction). The second spacer 7 may be made of a material having a high etching selectivity relative to the superlattice stack, such as silicon nitride, preferably the same material as the first spacer 6, so that the first spacer 6 and the second spacer 7 may be etched and removed simultaneously. The formation method includes but is not limited to PECVD, ALCVD, and the like.

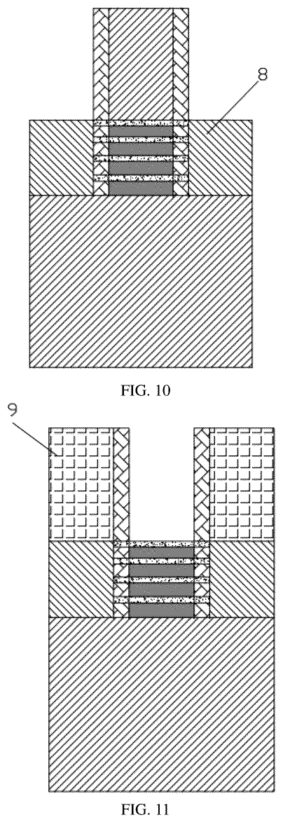

In Step S8, a doped semiconductor material is deposited in the source/drain area to form a source/drain region 8, as shown in FIG. 10 (a cross-sectional view in the Y-Y′ direction). In this step, the doping type is determined according to the transistor type. The semiconductor material may be silicon, silicon germanium, and the like.

In Step S9, a second dielectric layer 9 is formed on the source/drain region 8, and is flush with the dummy gate 5.

In Step S10, the dummy gate 5 is removed, as shown in FIG. 11 (a cross-sectional view in the Y-Y′ direction).

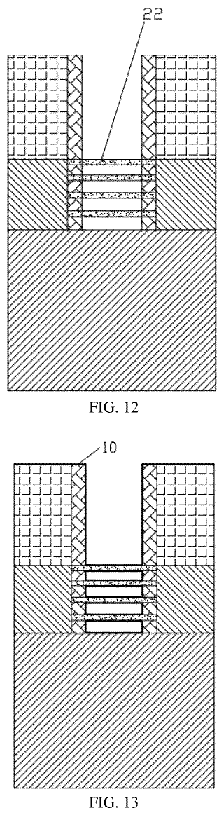

In Step S11, a part of the semiconductor materials in the superlattice stack is etched off to release a nanosheet channel. A stack formed by the nanosheets constitutes a plurality of conductive channels, as shown in FIG. 12 (a cross-sectional view in the Y-Y′ direction). For example, the silicon layer may be removed and the remaining silicon germanium layer 22 may be used as the nanosheet.

In Step S12, a gate-all-around is formed to surround the stack formed by the nanosheets. This step is usually performed in two steps, including the following Step S1201 and Step S1202.

In Step S1201, a gate dielectric layer 10 is deposited first, which may be made of a HK material, as shown in FIG. 13 (a cross-sectional view in the Y-Y′ direction).

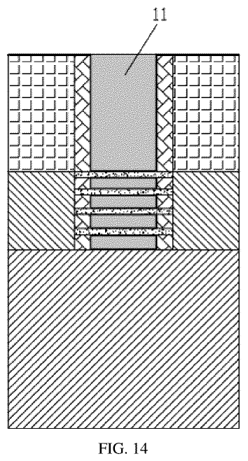

In Step S1202, a metal gate layer 11 is then deposited, as shown in FIG. 14 (a cross-sectional view in the Y-Y′ direction).

In Step S13, the first spacer 6 and the second spacer 7 are etched and removed to form a first empty spacer 121 and a second empty spacer 122, respectively. Afterwards, a silicon oxide layer 13 is filled by using a PECVD method. Since the filling of the hole by the PECVD method is small, the first empty spacer 121 has a large gap. Finally, surface planarization may be performed, as shown in FIG. 15 and FIG. 16 (FIG. 15 shows a cross-sectional view in the Y-Y′ direction, and FIG. 16 shows a cross-sectional view in the X-X′ direction). The first empty spacer 121 is located between the second dielectric layer 9 and the peripheral gate 112, and the second empty spacer 122 is located between the interlayer gate 111 and the source/drain region 8. Etching may be performed using dry etching or wet etching. For example, if the first spacer and the second spacer are made of silicon nitride, wet etching may be performed using a hot phosphoric acid solution to remove the first spacer and the second spacer. The second dielectric layer 9 may be made of silicon oxide, and stacked with the silicon oxide layer 13 to form the second dielectric layer 9′.

After Step S13, Step S14 may be optionally performed: the gas in the first empty spacer 121 and the second empty spacer 122 may be replaced with at least one of a reducing gas or an inert gas. If the gas is not replaced, the first empty spacer 121 and the second empty spacer 122 are naturally filled with the air. In order to improve the quality, the naturally filled air may be replaced with fresh air.

Compared with the related art, the present disclosure achieves the following technical effects:

(1) The empty spacer is provided between the source/drain region and the gate-all-around, and the gas medium such as air is used as the isolation material at the empty spacer, so that the parasitic capacitance of the device may be greatly reduced, and the operating speed of the device and the circuit may be effectively improved.

(2) On the basis of the traditional Nanosheet-GAAFET preparation process, after depositing the metal gate and performing CMP, high selectivity etching is performed on the exposed spacer structure to obtain the air spacer.

(3) During final filling, SiO₂ is filled by PECVD with a small filling ratio, so that a large gap may be formed in the empty spacer.

The embodiments of the present disclosure are described above. However, these embodiments are only for the purpose of illustration, and are not intended to limit the scope of the present disclosure. The scope of the present disclosure is defined by the appended claims and the equivalents thereof. Without departing from the scope of the present disclosure, various substitutions and modifications may be made by those skilled in the art, and these substitutions and modifications should all fall within the scope of the present disclosure.

What is claimed is:

1. A stacked nanosheet gate-all-around device with an air spacer, comprising:
a substrate with a shallow trench isolation structure on a surface of the substrate;
a nanosheet stacking portion provided above the substrate, wherein the nanosheet stacking portion comprises a stack formed by a plurality of nanosheets, and the stack formed by the nanosheets constitutes a plurality of conductive channels;
a gate-all-around surrounding the nanosheet stacking portion; and
a source/drain region located on two opposite sides of the nanosheet stacking portion, wherein an empty spacer is provided between the source/drain region and the gate-all-around,
wherein an interior of the empty spacer is filled with at least one of air, a reducing gas, or an inert gas.

2. The stacked nanosheet gate-all-around device with the air spacer according to claim 1, further comprising:
a second dielectric layer surrounding and covering the gate-all-around,
wherein the gate-all-around comprises an interlayer gate filled among the plurality of nanosheets and a peripheral gate surrounding the nanosheet stacking portion, and
wherein the empty spacer comprises a first empty spacer located between the second dielectric layer and the peripheral gate, and a second empty spacer located between the interlayer gate and the source/drain region.

3. The stacked nanosheet gate-all-around device with the air spacer according to claim 1, wherein the nanosheet is made of a silicon germanium material.

4. The stacked nanosheet gate-all-around device with the air spacer according to claim 1, wherein a width of the nanosheet is in a range of 5 nm to 50 nm, and a thickness of the nanosheet is in a range of 3 nm to 20 nm.

5. The stacked nanosheet gate-all-around device with the air spacer according to claim 1, wherein the shallow trench isolation structure is made of silicon oxide.

6. The stacked nanosheet gate-all-around device with the air spacer according to claim 1, wherein the gate-all-around comprises a gate dielectric layer and a metal gate layer.

7. A method of manufacturing a stacked nanosheet gate-all-around device with an air spacer, comprising:
providing a substrate;
forming a sacrificial layer on the substrate;
forming a first semiconductor layer on an upper surface of the sacrificial layer;
epitaxially growing a superlattice stack on a surface of the first semiconductor layer, wherein the superlattice stack is composed of different semiconductor materials alternatively stacked;
etching the superlattice stack and a partial thickness of the first semiconductor layer to form a fin;
forming a first dielectric layer on the first semiconductor layer as a shallow trench isolation, wherein an upper surface of the first dielectric layer is not higher than a bottom of the superlattice stack;
depositing a dummy gate on the fin and forming a first spacer on a sidewall of the dummy gate;
etching the superlattice stack in the fin to release a source/drain area;
forming a second spacer on a sidewall of the superlattice stack in the fin;
depositing a doped semiconductor material in the source/drain area to form a source/drain region;
forming a second dielectric layer on the source/drain region, wherein the second dielectric layer is flush with the dummy gate;
removing the dummy gate;
etching off a part of the semiconductor materials in the superlattice stack to release a nanosheet channel, wherein a stack formed by the nanosheets constitutes a plurality of conductive channels;
forming a gate-all-around to surround the stack formed by the nanosheets;
etching and removing the first spacer and the second spacer to form a first empty spacer and a second empty spacer, respectively, and
filling a third dielectric layer.

8. The method according to claim 7, further comprising:
replacing a gas in the first empty spacer and the second empty spacer with at least one of air, a reducing gas, or an inert gas.

9. The method according to claim 7, wherein the filling a third dielectric layer comprises: filling silicon oxide by using a PECVD method.

10. The method according to claim 7, wherein the first spacer and the second spacer are made of silicon nitride, and the first spacer and the second spacer are etched by using a phosphoric acid solution.
